(19) United States
(12) Patent Application Publication
(10) Pub. No.: US 2008/0128187 A1
(43) Pub. Date: Jun. 5, 2008

(54) Transportation device adapted with a solar photo module

(75) Inventor: Henry Hu, Kwei Shan Shiang (TW)

Correspondence Address: TROXELL LAW OFFICE PLLC, SUITE 1404, 5205 LEESBURG PIKE, FALLS CHURCH, VA, 22041, US

(73) Assignee: Lucky Power Technology Co., Ltd.

(21) Appl. No.: 11/607,054

(22) Filed: Dec. 1, 2006

(51) Int. Cl. B60L 8/00; H01L 31/042

(52) U.S. Cl. 180/65.3; 136/244

(57) ABSTRACT

A transportation device adapted with a solar photo module includes a main frame, at least two side frames disposed on both sides of the main frame; a locating gap to accommodate the solar photo module is disposed to each side frame; and the solar photo module absorbs solar energy to convert it into electric power serving auxiliary power for consumption by the transportation device.

### BACKGROUND OF THE INVENTION

(a) Field of the Invention

The present invention is related to a transportation device adapted with a solar photo module, and more particularly, to one in simple structure that operates on auxiliary electric power converted from solar energy.

(b) Description of the Prior Art

While the mankind enjoys a life that is extremely convenient in a highly civilized environment thanks to excessive development, the cost yet is that all creatures in the world have to scarify their rights of survival. For example, the disappearance of the ozone layer takes away the shade against the exposure of Ultraviolet (UV) lights. The hole in the ozone layer causes the temperature of the earth is on the rising and bizarre weather conditions including snowing in June. As a result, all creatures living in this planet are subject to the consequences the mankind is the only one to blame. What could be worse is that generations to come of the human being would have to suffer if we, this very generation, have not taken serious look at the phenomenon nor taken corrective action.

According to survey, fuel consumed in transportation device by man is the primary contamination to the environment. Pollution presents wherever the transportation device moves to, making the pollution directly spreading over any place over, on and under the earth. Aircrafts directly spray fuel wastes into the sea and land creating a 3D pollution to fast deteriorate the natural environment. Sea vessels cruising on the oceans directly charge their fuel wastes into the ocean to significantly affect the life forms therein. Up to now, how to introduce a substitute energy or how to minimize the consumption of the fuels we have now without compromising the existing purpose and efficiency has been a topic deserving our in-depth exploration. Therefore, with the environment awareness addressed in these two decades, scientists and biologists continue to work hard on how to push forward human progress to another peak yet without slowing down the advancing pace and further damaging the environment. In the field of industrial technology, R&D of electric power driven cars, use of solar energy, and manufacturing of anthracite coal are proved human efforts among others to the environmental protection and substantial undertakings in evolution that tolerates.

In the prior art, single power source appears to be everywhere as seen in various types of transportation device, e.g., diesel engine, gasoline engine, solar energy power system, power driven system, etc. Some of them though providing excellent power effects and enduring performance suffer environmental problems while others designed with environmental concepts fail to achieve the power effects desired. On the other hand, cars operating on electric power and solar energy though attempting to exclude the use of fuel of conventional fuel consuming engine, are not reliable. A new concept of a new power source that combines the traditional energy source is taking shape to achieve the purposes of excellent power effects, longwearing and environmental awareness at the same time.

### SUMMARY OF THE INVENTION

The primary purpose of the present invention is to provide a transportation device that utilizes auxiliary electric power converted from solar energy in a simple structure.

To achieve the purpose, the present invention includes a main frame, multiple side frames disposed to the main frame, a locating gap on each side frame to accommodate a solar photo module for the main frame to be secured in the transportation device, and the solar photo module absorbs solar energy to convert it to electric power for consumption by the transportation device.

### BRIEF DESCRIPTION OF THE DRAWINGS

FIG. 1 is a perspective view showing a first preferred embodiment of the present invention.

FIG. 2 is a schematic view showing a solar photo module and two side frames in the first preferred embodiment of the present invention.

FIG. 3 is a schematic view showing a locating structure for the solar photo module of the present invention.

FIGS. 4(A) and 4(B) are exploded views of a solar photo module and two side frames in a second preferred embodiment of the present invention.

FIG. 5 is a schematic view showing a structure of the solar photo module and two side frames in the second preferred embodiment of the present invention.

FIG. 6 is a perspective view of a second preferred embodiment of the present invention adapted with the solar photo module.

FIG. 7 is a schematic view showing another structure of the solar photo module and two side frames of the present invention.

FIG. 8 is a schematic view showing a third preferred embodiment of the solar photo module and two side frames of the present invention.

FIG. 9 is a perspective view showing another structure of the present invention adapted with the solar photo module.

FIG. 10 is a schematic view showing a structure of the solar photo module connected to a controller.

FIG. 11 is a schematic view showing a structure of a start up device in a car in the present invention.

FIG. 12 is a perspective view of a structure of the car adapted with the solar photo module.

FIG. 13 is a schematic view showing a structure of the solar photo module connected to each light emitting diode in the present invention.

### DETAILED DESCRIPTION OF THE PREFERRED EMBODIMENTS

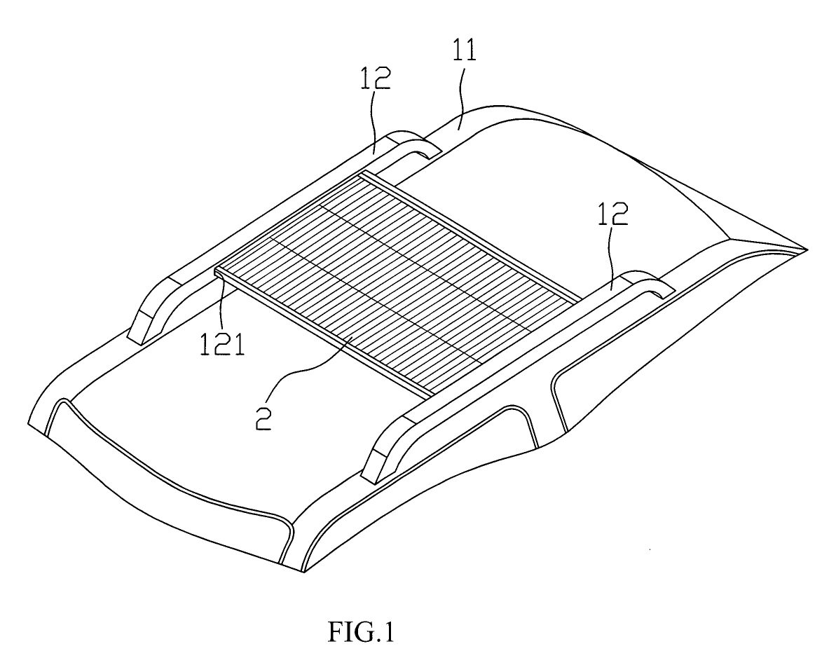

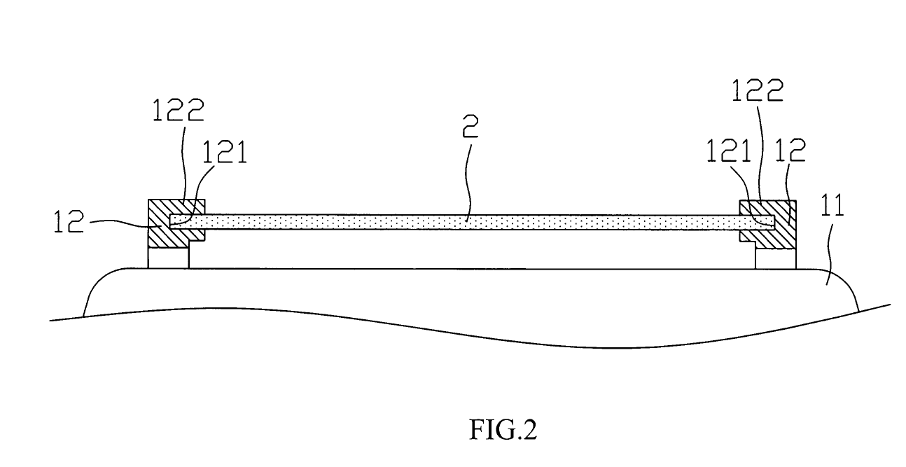

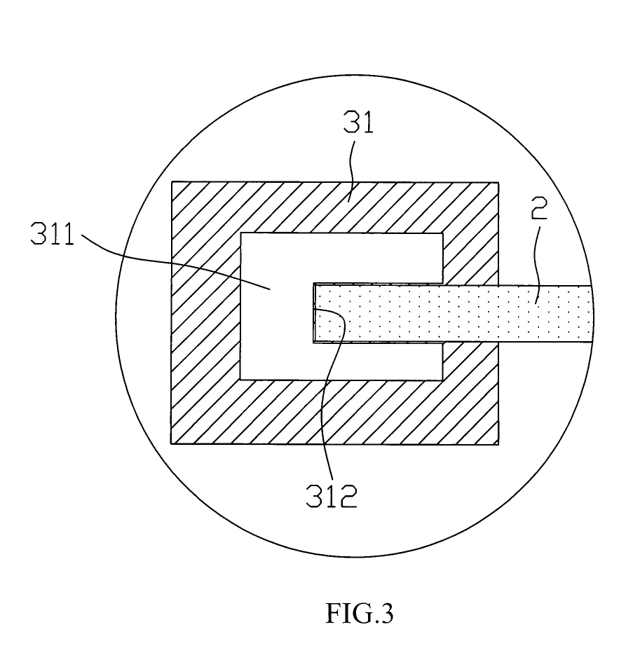

The transportation device in the present invention may be related to an automobile, motorcycle, aircraft, yacht, or sea vessel. As illustrated in FIG. 1, a first preferred embodiment of the present invention related to an automobile includes a main frame 11, and the main frame 11 is related to a roof deck of the automobile. Two side frames 12 in the preferred embodiment are disposed and made integrated or separately adapted to the main frame 11. A locating gap 121 is disposed to each side frame 12. As illustrated in FIG. 2, the locating gap 121 is disposed on the inner side of each side frame 12 and both locating gap 121 are facing each other to accommodate the solar photo module 2. A press portion 122 is disposed to each side frame 12 in relation to the top over the locating gap 121.

Wherein, the solar photo module 2 is secured to a mold 31. As illustrated in FIG. 3, the mold 31 is provided with a side frame mold cavity 311 and a locating gap mold cavity 312. The solar photo module 2 is first placed in the locating gap mold cavity 312, followed with mold injection and removing procedure to complete the structure as illustrated in FIGS. 1 and 2 to receive the solar photo module 2 in both locating gaps 121 while being secured to the transportation device by means of both press portions 122.

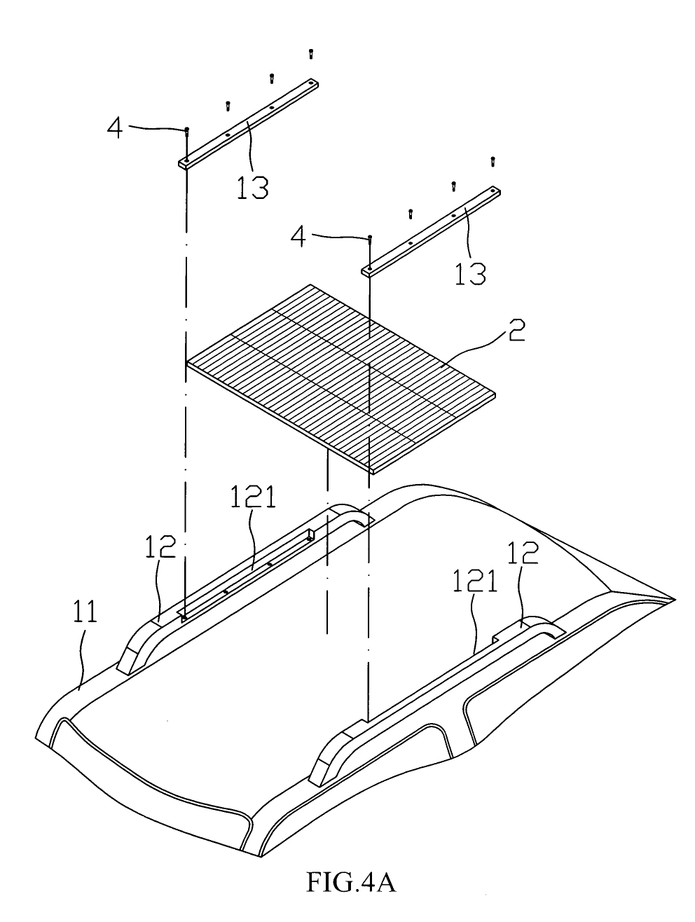

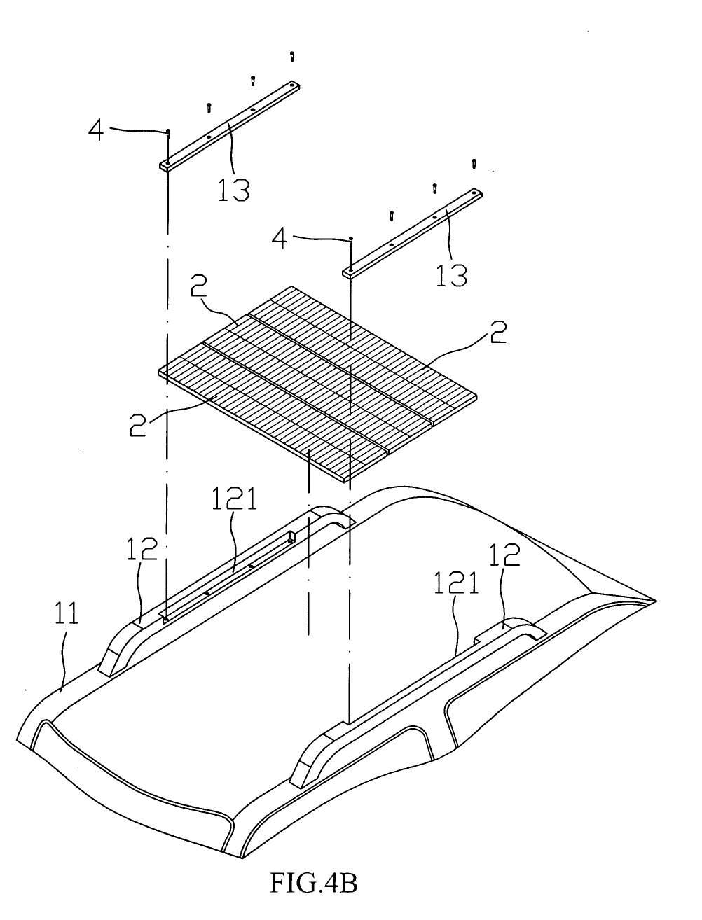

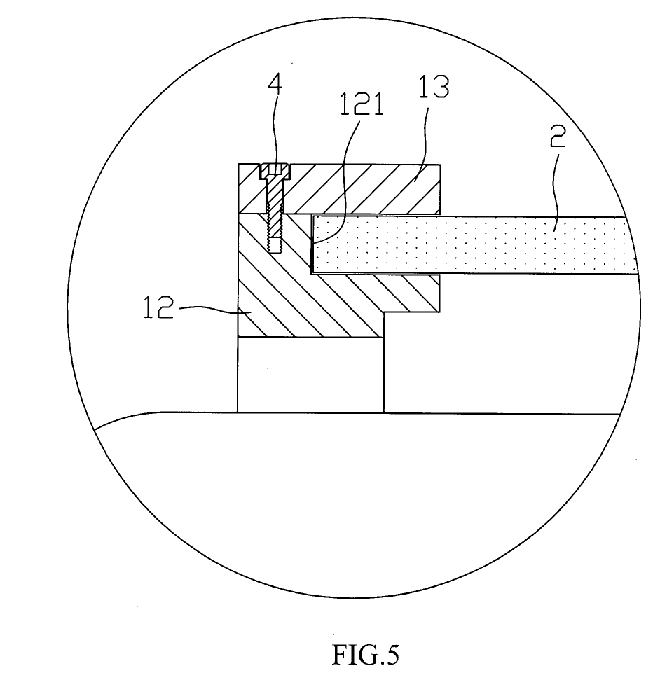

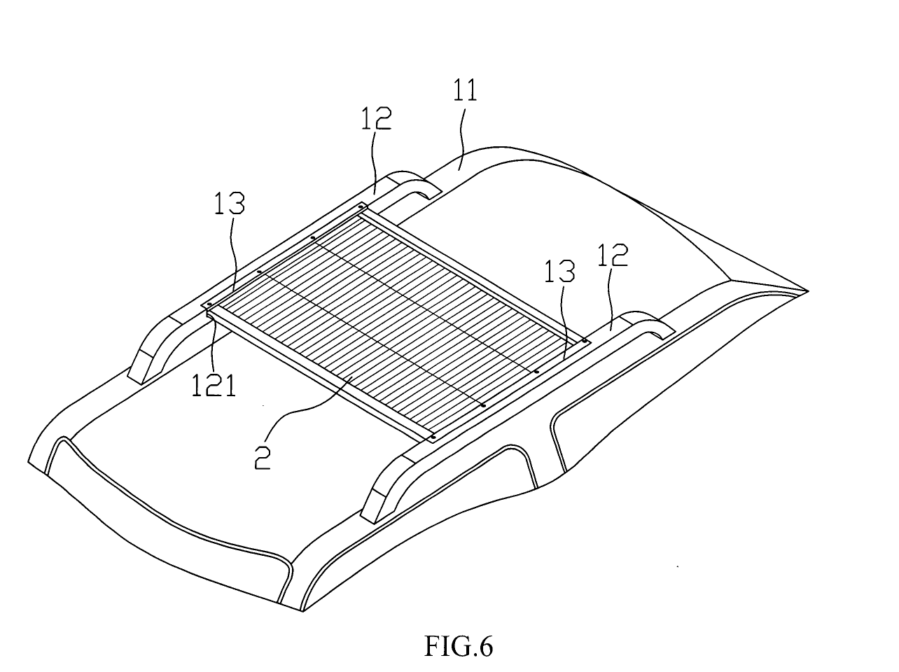

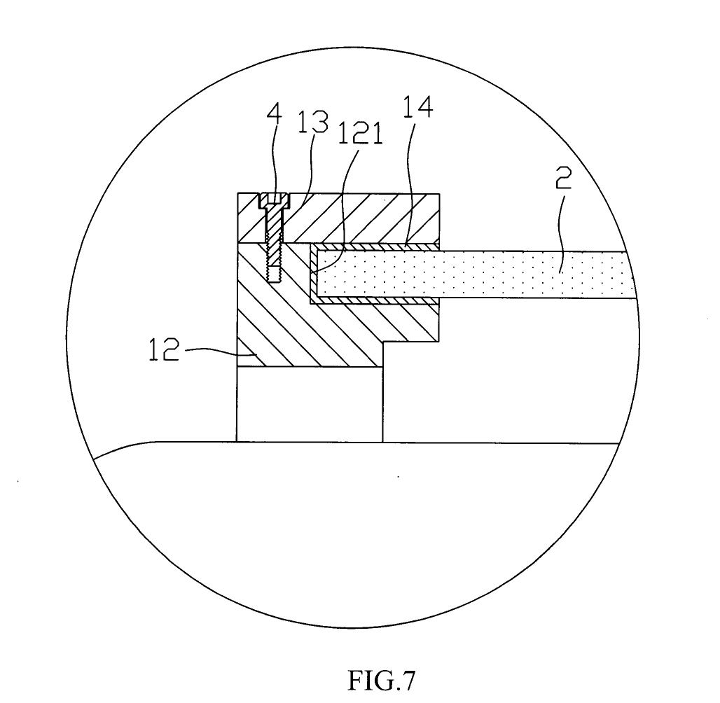

Now referring to FIG. 4(A) for a second preferred embodiment of the present invention, two side frames 12 are provided to the main frame 11, the locating gap 121 is provided to each side frame 12, and both locating gaps 121 are facing each other to accommodate a single sheet of the solar photo module 2, or multiple solar photo modules 2 as illustrated in FIG. 4(B). Also referring to FIG. 5, a pressure strip 13 is disposed over the top of the solar photo module 2 near to the locating gap 121, and both of the side frame 12 and the pressure strip 13 are secured to each other by means of a locating member 4. As illustrated, the locating member may be related to a screw to secure the pressure strip 13 and the side frame 12. The pressure strip 13 by pressing against the top of the solar photo module 2 to secure it to the transportation device as illustrated in FIG. 6. A pad buffer 14 may further fill in where between the locating gap 121 and the solar photo module 2 as illustrated in FIG. 7.

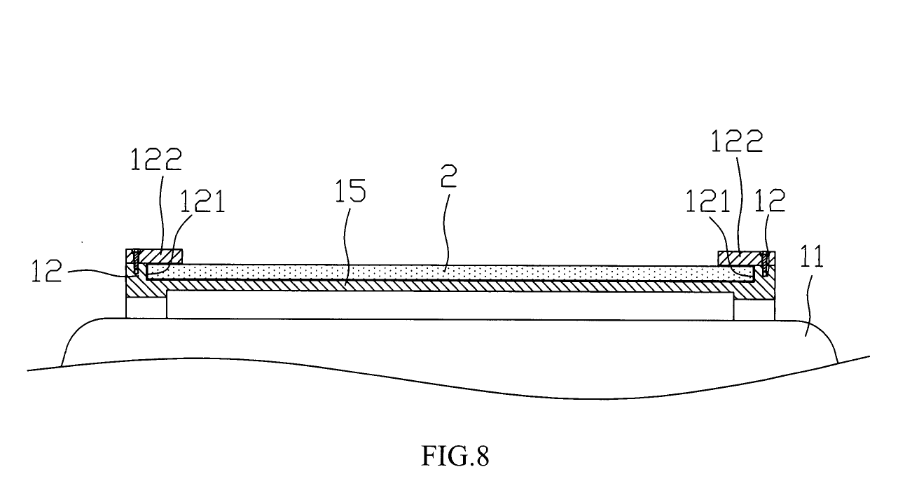

Now referring to FIG. 8 for a third preferred embodiment of the present invention, two strips 15 in parallel to each other are provided between and connecting both side frames 12, and each strip 15 extends from the bottom of a locating gap 121 to that of the other locating gap 121 so to bear the solar photo module 2 when received by two locating gaps 121.

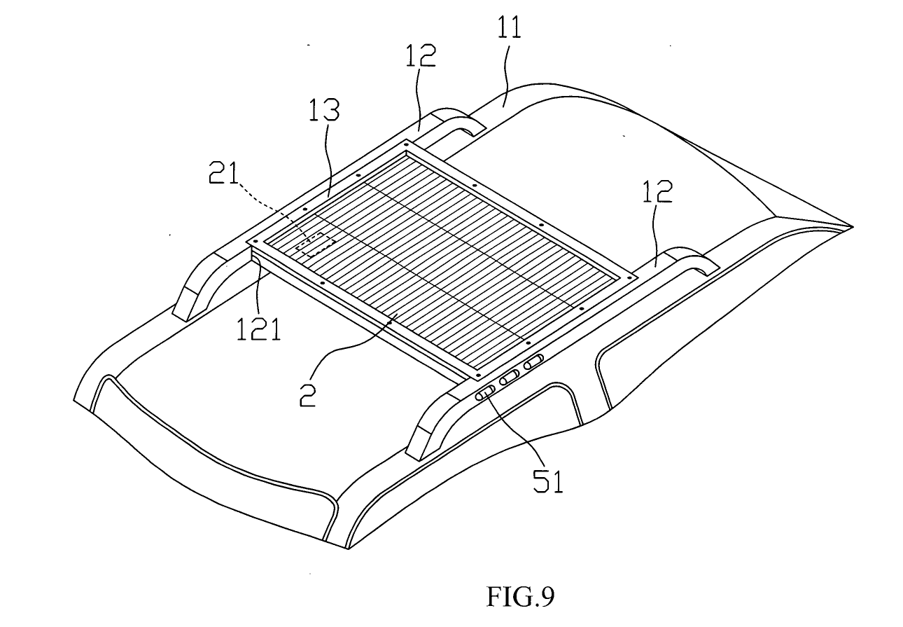

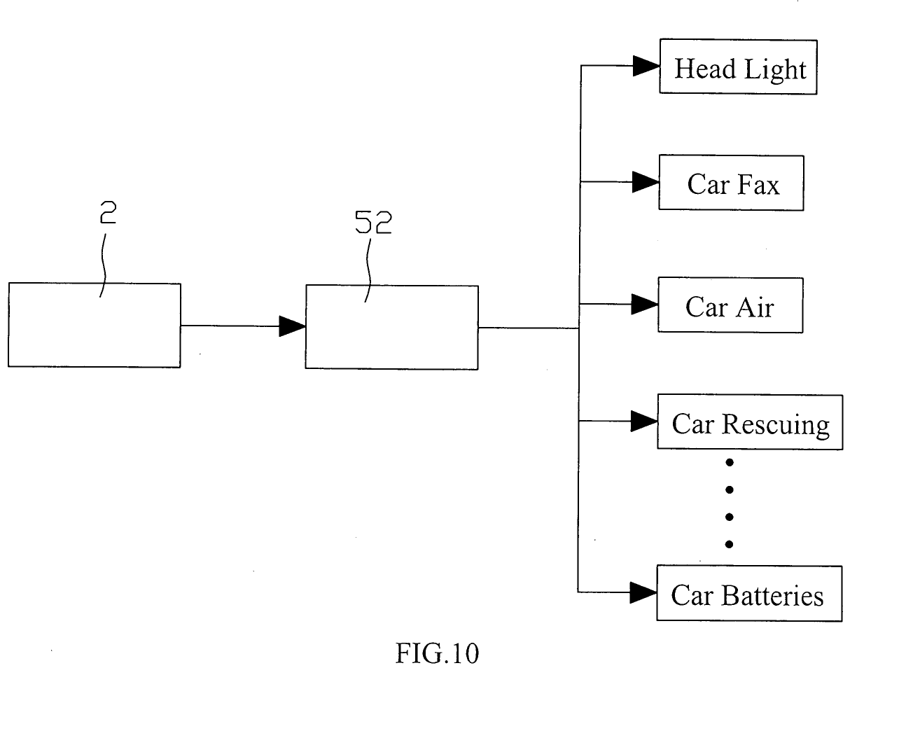

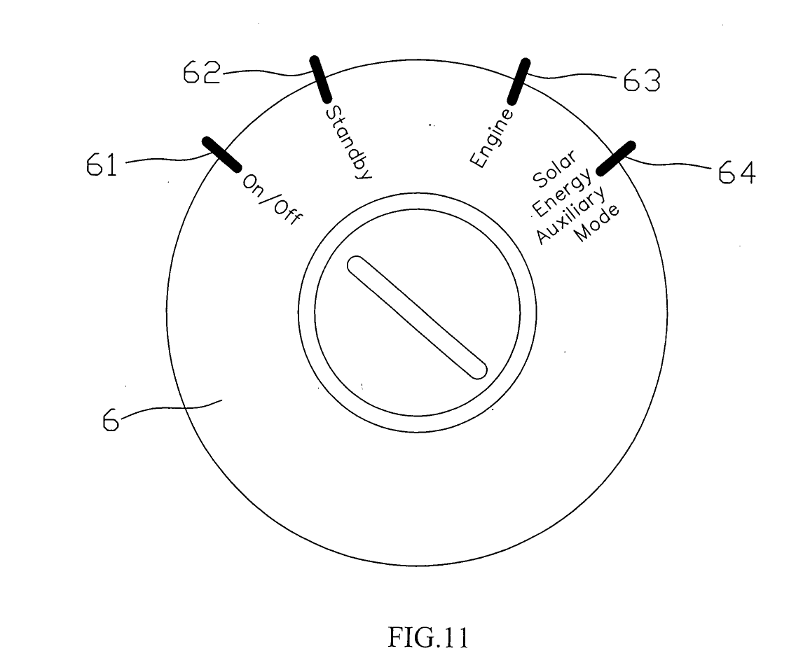

A direction indicator 51 is further disposed to the main frame 11 as illustrated in FIG. 9. The direction indicator 51 may be related to a light emitting diode (LED) to indicate the turning direction of the automobile. An Identity (ID) chip 21 may be further disposed to, for example by printing on the solar photo module 2 to be powered by the solar photo module for achieving burglarproof purpose. A controller 52 is connected to the solar photo module 2 as illustrated in FIG. 10 and the controller 52 is further connected to a car-laden power source, e.g., headlight, fan, air cooling compressor, rescuing system, or batteries to control the power supply from the solar photo module 2 to the power source in the car. A solar energy auxiliary mode 64 may be added to an existing ON/Off 61, and multi-stage activation point including standby mode 62, an engine mode 63 on an ignition switch 6 (e.g., the keyhole) in the automobile as illustrated in FIG. 11. When switched to the solar energy auxiliary mode 64, the controller 52 permits power supply to the car-laden power supply without consuming the electricity stored in the car batteries.

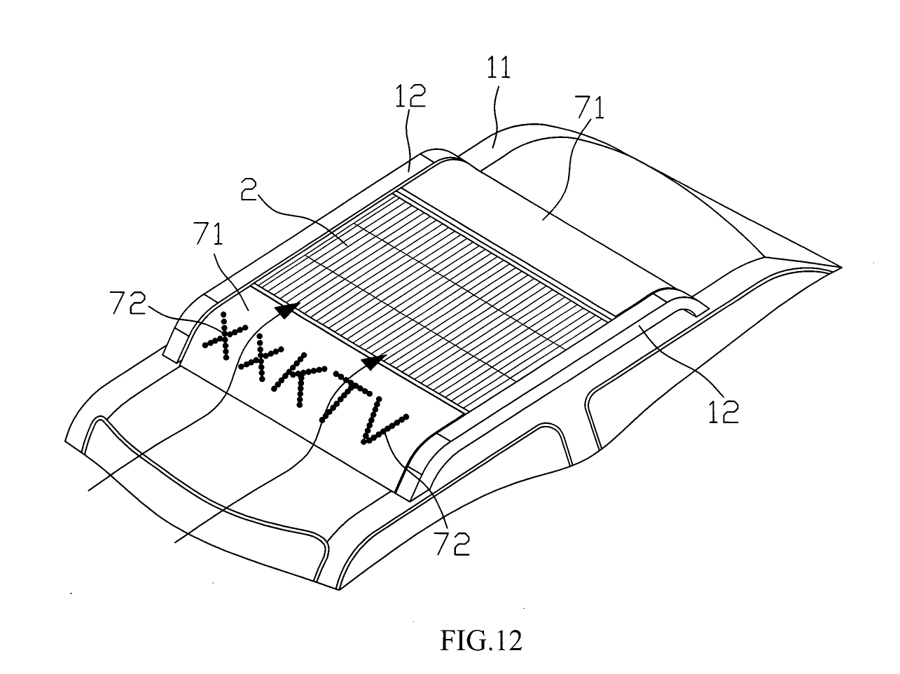

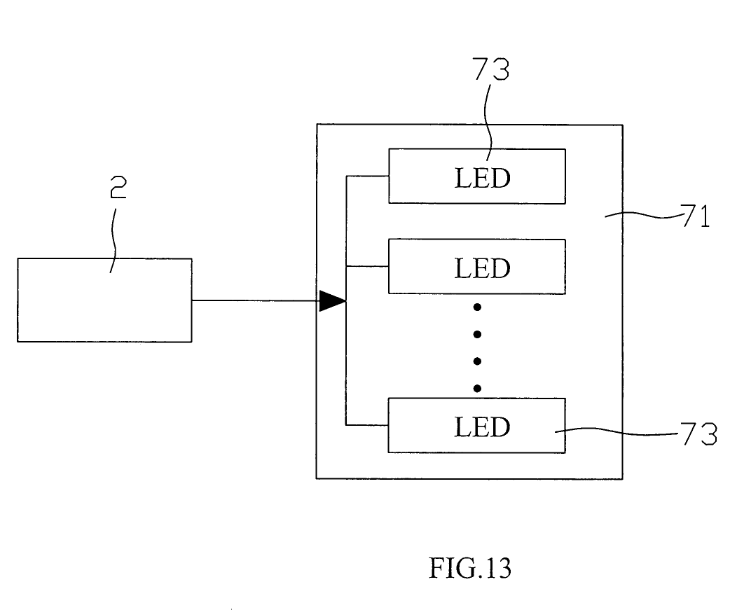

Furthermore, a wing 71 as illustrated in FIG. 12 is disposed to an outer side of the solar photo module 2 or each wing 71 is disposed to both outer sides of the solar photo module 2. The wind 71 is streamlined to reduce wind resistance coefficient for promoting acceleration performance. An AD billboard 72 may be further disposed on the wing 71 and multiple LEDs 73 with each powered by the solar photo module 2 are provided to the Advertisement (AD) billboard 72 as illustrated in FIG. 13 without relying upon power supply from the car batteries. Therefore those LEDs remain lighted to maintain its display purpose even with the engine killed.

The prevent invention provides an improved structure of a transportation device adapted with a solar photo module, and the application for a utility patent is duly filed accordingly. However, it is to be noted that the preferred embodiments disclosed in the specification and the accompanying drawings are not limiting the present invention; and that any structure, installation, or characteristics that is same or similar to that of the present invention should fall within the scope of the purposes and claims of the present invention.

I claim,

1. A transportation device adapted with a solar photo module including a main frame, one or a plurality of side frame mounted to the main frame and having one or a plurality of locating gaps; and one or a plurality solar photo module disposed to the side frame by means of the locating gap and secured to the transportation device.

2. The transportation device adapted with a solar photo module as claimed in claim 1, wherein at least two side frames are disposed to the main frame, and each the locating gap is provided on the side of the side frame in the direction facing the other locating gap provided on the other side frame.

3. The transportation device adapted with a solar photo module as claimed in claim 2, wherein a press portion is disposed to the side frame at where in relation to the top over the locating gap and made an integral part of the side frame.

4. The transportation device adapted with a solar photo module as claimed in claim 2, wherein the locating gap accommodate the solar photo module, and a pressure strip is disposed to the solar photo module near to the locating gap.

5. The transportation device adapted with a solar photo module as claimed in claim 4, wherein both of the side frame and the pressure strip are secured to each other by means of a locating member.

6. The transportation device adapted with a solar photo module as claimed in claim 5, wherein the locating member is a screw.

7. The transportation device adapted with a solar photo module as claimed in claim 4, wherein two strips in parallel with each other are disposed between and connecting both side frames, and each strip extends from the bottom of a locating gap to that of the other locating gap.

8. The transportation device adapted with a solar photo module as claimed in claim 4, wherein a pad buffer is filled at where between the locating gap and the solar photo module.

9. The transportation device adapted with a solar photo module as claimed in claim 1, wherein the side frame is made an integral part of or separately assembled to the main frame.

10. The transportation device adapted with a solar photo module as claimed in claim 1, wherein the transportation device is related to an automobile, and the main frame is a roof deck of the automobile.

11. The transportation device adapted with a solar photo module as claimed in claim 1, wherein a direction indicator is disposed to the main frame.

12. The transportation device adapted with a solar photo module as claimed in claim 1, wherein a controller is further connected to the solar photo module.

13. The transportation device adapted with a solar photo module as claimed in claim 1, wherein an ID chip is further provided to the solar photo module.

14. The transportation device adapted with a solar photo module as claimed in claim 1, wherein a wing is disposed to the side frame; the wing is located on an outer side of the solar photo module or each to both outer sides of the solar photo module.

15. The transportation device adapted with a solar photo module as claimed in claim 1, wherein an AD billboard is disposed at where the wing is provided, the AD billboard is comprised of multiple light emitting diodes; and the solar photo module supplies power to each light emitting diode.
